(19) United States
(12) Patent Application Publication
(10) Pub. No.: US 2025/0157899 A1
(43) Pub. Date: May 15, 2025

(54) PACKAGE STRUCTURE AND FABRICATION METHOD THEREOF

(71) Applicant: Vanguard International Semiconductor Corporation, Hsinchu (TW)

(72) Inventors: Hsiu-Mei Yu, Hsinchu City (TW); Wei-Chan Chang, Taoyuan City (TW); Cheng-Yi Hsieh, Hsinchu County (TW)

(73) Assignee: Vanguard International Semiconductor Corporation, Hsinchu (TW)

(21) Appl. No.: 18/507,114

(22) Filed: Nov. 13, 2023

(51) Int. Cl. H01L 23/498; H01L 23/00; H01L 23/31

(52) U.S. Cl. CPC H01L 23/49811; H01L 23/3107; H01L 23/49844; H01L 24/32; H01L 24/48; H01L 24/73; H01L 2224/32245; H01L 2224/48227; H01L 2224/73265; H01L 2924/13064

(57) ABSTRACT

A package structure includes a lead frame, a die, a bonding wire, a first solder and a molding material. The lead frame includes a cavity, and the die is disposed in the cavity. The die includes a substrate, a bonding pad and a backside metal layer. The bonding pad is disposed on a first surface of the substrate. The backside metal layer is disposed on a second surface of the substrate. The bonding wire electrically connects the bonding pad of the die to the lead frame. The first solder is disposed between the backside metal layer and the cavity. The die is soldered onto the lead frame through the first solder. The molding material encapsulates the die and the bonding wire, and also covers the lead frame.

### BACKGROUND OF THE INVENTION

### 1. Field of the Invention

The present disclosure relates generally to die packaging technology, and more particularly to package structures including a lead frame and fabrication methods thereof.

### 2. Description of the Prior Art

With the development of 5G communication, electric vehicle industries and various electronic products, the demand for high-frequency and high-power semiconductor devices is also growing. These high-frequency and high-power semiconductor devices are such as high-frequency transistors, high-power field-effect-transistors, or high electron mobility transistors (HEMTs), and are generally made of compound semiconductors, such as gallium nitride (GaN), silicon carbide (SiC) or other group III-V compound semiconductors. The compound semiconductors have the characteristics of high operating frequency, high breakdown voltage, low on-resistance, etc. These semiconductor devices made of compound semiconductors are usually used under the operating conditions of high voltage and high temperature. In general, the high-frequency and high-power semiconductor devices may be bonded and attached on a printed circuit board by conventional packaging methods, such as die bonding, wire bonding, and molding methods.

However, the conventional die packages are usually more suitable for the semiconductor devices operated at low voltage and room temperature. For the semiconductor devices operated at high voltage and high temperature, the conventional die packages cannot fully use the advantages of new materials in all aspects to achieve the optimization of packages.

### SUMMARY OF THE INVENTION

In view of this, the present disclosure provides package structures and fabrication methods thereof, which are suitable for semiconductor devices operated at high voltage and high temperature. In the package structures, a die has a backside metal layer and a lead frame has a cavity. The die is disposed in the cavity of the lead frame, and the backside metal layer of the die is bonded onto the lead frame through a solder. The main advantages of some embodiments of the present disclosure are that the die utilizes the excellent heat dissipation capability of a composite substrate such as a QST substrate, and the height of the overall package structure is reduced. Therefore, the heat dissipation effect of the package structures is greatly improved. Moreover, for the mass production, the lead frame is still used in the package structures, so that the package structures are produced in batches and suitable for current mass production equipment to save the production costs.

According to an embodiment of the present disclosure, a package structure is provided and includes a lead frame, a die, a bonding wire, a first solder, and a molding material. The lead frame includes a cavity, and the die is disposed in the cavity of the lead frame. The die includes a substrate, a bonding pad and a backside metal layer, where the bonding pad is disposed on a first surface of the substrate, and the backside metal layer is disposed on a second surface of the substrate. The bonding wire electrically connects the bonding pad of the die to the lead frame. The first solder is disposed between the backside metal layer and the cavity, and the die is soldered onto the lead frame through the first solder. The molding material encapsulates the die and the bonding wire, and covers the lead frame.

According to an embodiment of the present disclosure, a method of fabricating a package structure is provided and includes the following steps. A lead frame is provided and a cavity is formed in the lead frame. A die is provided and includes providing a substrate having a first surface and a second surface, forming a bonding pad on the first surface, and forming a backside metal layer on the second surface. The die is disposed in the cavity, and a first solder is used to solder the backside metal layer of the die onto the lead frame. A bonding wire is formed to electrically connect the bonding pad of the die to the lead frame. In addition, the die and the bonding wire are encapsulated by a molding material, and the molding material covers the lead frame.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

Aspects of the present disclosure are best understood from the following detailed description when read with the accompanying figures. It is noted that, in accordance with the standard practice in the industry, various features may not be drawn to scale. In fact, the dimensions of the various features may be arbitrarily increased or reduced for clarity of discussion.

FIG. 1 is a schematic cross-sectional view of a package structure according to an embodiment of the present disclosure.

FIG. 2 shows schematic cross-sectional views of a substrate of a die according to some embodiments of the present disclosure.

FIG. 3 is a schematic cross-sectional view of a package structure according to another embodiment of the present disclosure.

FIG. 4, FIG. 5, FIG. 6, FIG. 7 and FIG. 8 are schematic cross-sectional views of some stages of a method of fabricating a package structure according to an embodiment of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “under,” “lower,” “over,” “above,” “on,” “upper” and the like, may be used herein for ease of description to describe one element or feature's relationship to another element(s) or feature(s) as illustrated in the figures. The spatially relative terms are intended to encompass different orientations of the package structure in use or operation in addition to the orientation depicted in the figures. For example, if the package structure in the figures is turned over, elements described as “below” and/or “beneath” other elements or features would then be oriented “above” and/or “over” the other elements or features. The package structures may be otherwise oriented (rotated 90 degrees or at other orientations) and the spatially relative descriptors used herein may likewise be interpreted accordingly.

It is understood that, although the terms first, second, third, etc. may be used herein to describe various elements, components, regions, layers and/or sections, these elements, components, regions, layers and/or sections should not be limited by these terms. These terms may be only used to distinguish one element, component, region, layer and/or section from another region, layer and/or section. Terms such as “first,” “second,” and other numerical terms when used herein do not imply a sequence or order unless clearly indicated by the context. Thus, a first element, component, region, layer and/or section discussed below could be termed a second element, component, region, layer and/or section without departing from the teachings of the embodiments.

As disclosed herein, the term “about” or “substantial” generally means within 20%, 10%, 5%, 3%, 2%, 1%, or 0.5% of a given value or range. Unless otherwise expressly specified, all of the numerical ranges, amounts, values and percentages disclosed herein should be understood as modified in all instances by the term “about” or “substantial”. Accordingly, unless indicated to the contrary, the numerical parameters set forth in the present disclosure and attached claims are approximations that can vary as desired.

Furthermore, as disclosed herein, the terms “coupled to” and “electrically connected to” include any directly and indirectly electrical connecting means. Therefore, if it is described in this document that a first component is coupled or electrically connected to a second component, it means that the first component may be directly connected to the second component, or may be indirectly connected to the second component through other components or other connecting means.

In the present disclosure, a “group III-V compound semiconductor” refers to a compound semiconductor that includes at least one group III element and at least one group V element, where group III element may be boron (B), aluminum (Al), gallium (Ga) or indium (In), and group V element may be nitrogen (N), phosphorous (P), arsenic (As), or antimony (Sb). Furthermore, the group III-V compound semiconductor may refer to, but not limited to, gallium nitride (GaN), indium phosphide (InP), aluminum arsenide (AlAs), gallium arsenide (GaAs), aluminum gallium nitride (AlGaN), indium aluminum gallium nitride (InAlGaN), indium gallium nitride (InGaN), aluminum nitride (AlN), gallium indium phosphide (GaInP), AlGaAs, InAlAs, InGaAs, or the like, or the combination thereof.

Although the disclosure is described with respect to specific embodiments, the principles of the disclosure, as defined by the claims appended herein, can obviously be applied beyond the specifically described embodiments of the disclosure described herein. Moreover, in the description of the present disclosure, certain details have been left out in order to not obscure the inventive aspects of the disclosure. The details left out are within the knowledge of a person having ordinary skill in the art.

The present disclosure relates to package structures of dies and fabrication methods thereof. A backside metal layer is formed on the back surface of a die, and a cavity is formed in a lead frame. The die is disposed in the cavity of the lead frame, and the backside metal layer of the die is soldered onto the lead frame through a solder, thereby reducing the height of the package structure and greatly improving the heat dissipation effect of the package structure. The package structures are more suitable for semiconductor devices operated at high voltage and high temperature, such as high-frequency and high-power semiconductor devices made of group III-V compound semiconductors.

Furthermore, in some embodiments of the present disclosure, a substrate of the die may be a composite substrate such as a Qromis Substrate Technology (QST) substrate. The thermal conductivity of the QST substrate is hundreds of times more than that of a silicon substrate, so that the QST substrate provides excellent heat dissipation capability for the die. The die using the QST substrate combined with the package structures of the present disclosure greatly improves the heat dissipation effect of the package structures of dies.

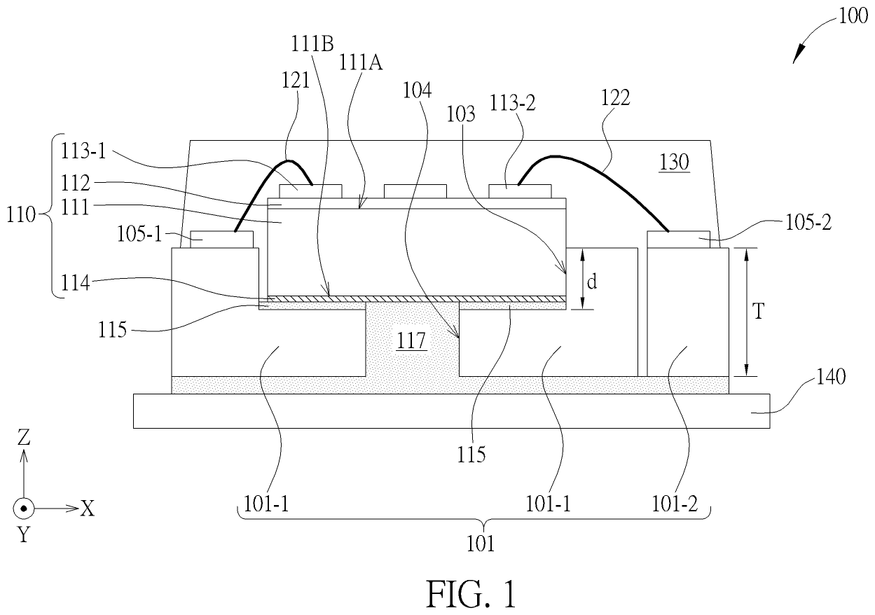

FIG. 1 is a schematic cross-sectional view of a package structure 100 according to an embodiment of the present disclosure. The package structure 100 includes a lead frame 101, such as a lead frame made of copper or other metals with better heat dissipation. The lead frame 101 includes a first portion 101-1 and a second portion 101-2 spaced apart from each other, and a cavity 103 is formed in the first portion 101-1 of the lead frame 101. In some embodiments, in the Z-axis direction, the depth d of the cavity 103 may be one-quarter to one-half of the thickness T of the lead frame 101, so that the lead frame 101 having the cavity 103 still provides sufficient support for dies. For example, the thickness T of the lead frame 101 may be about 400 micrometers (μm), and the depth d of the cavity 103 may be about 100 μm to about 200 μm, but not limited thereto. Moreover, a first conductive pad 105-1 and a second conductive pad 105-2 may be disposed on the first portion 101-1 and the second portion 101-2 of the lead frame 101, respectively, for subsequently wire bonding between the lead frame 101 and a die. In this embodiment, the lead frame 101 may further include a through hole 104 formed under the bottom surface of the cavity 103. The through hole 104 penetrates a thinner portion of the lead frame 101 located below the cavity 103, so that the through hole 104 is connected to the cavity 103.

In addition, the package structure 100 includes a die 110 disposed in the cavity 103 of the lead frame 101. The die 110 includes a substrate 111 that has a first surface 111A opposite to a second surface 111B. In one embodiment, a semiconductor layer 112 may be formed on the first surface 111A of the substrate 111, and multiple bonding pads such as a first bonding pad 113-1 and a second bonding pad 113-2 are formed on the semiconductor layer 112 and laterally spaced from each other. In some embodiments, the composition of the semiconductor layer 112 includes silicon, polysilicon or group III-V compound semiconductors. The semiconductor layer 112 may be a single semiconductor layer or a stack of semiconductor layers. The single semiconductor layer may be a silicon layer, a polysilicon layer or a group III-V compound semiconductor layer. The stack of semiconductor layers may include multiple semiconductor sub-layers, such as sub-layers made of various group III-V compound semiconductors. The composition of each group III-V compound semiconductor sub-layer is, for example, gallium nitride (GaN), indium phosphide (InP), aluminum arsenide (AlAs), aluminum nitride (AlN), gallium arsenide (GaAs), aluminum gallium nitride (AlGaN), indium aluminum gallium nitride (InAlGaN), indium gallium nitride (InGaN), gallium indium phosphide (GaInP), aluminum gallium arsenide (AlGaAs), indium aluminum arsenide (InAlAs) or indium gallium arsenide (InGaAs), but not limited thereto. In some embodiments, the semiconductor layer 112 may be used to fabricate a high electron mobility transistor (HEMT) or other high-power transistors. The multiple bonding pads on the semiconductor layer 112, such as the first bonding pad 113-1 and the second bonding pad 113-2, are electrically connected to electrodes of the transistor respectively. The first bonding pad 113-1 and the second bonding pad 113-2 may be a single-layered structure or a multi-layered structure. For example, the composition of the single-layered structure may include Au, Ag or Cu. The composition of the multi-layered structure may be selected from a group consisting of Ti/Ni/Au, Ti/Cu, Ti/Au, Cu/Ni/Au, Ni/Pd/Au, Ni/Au, Au/As, Al/Ni/Ag and combinations thereof.

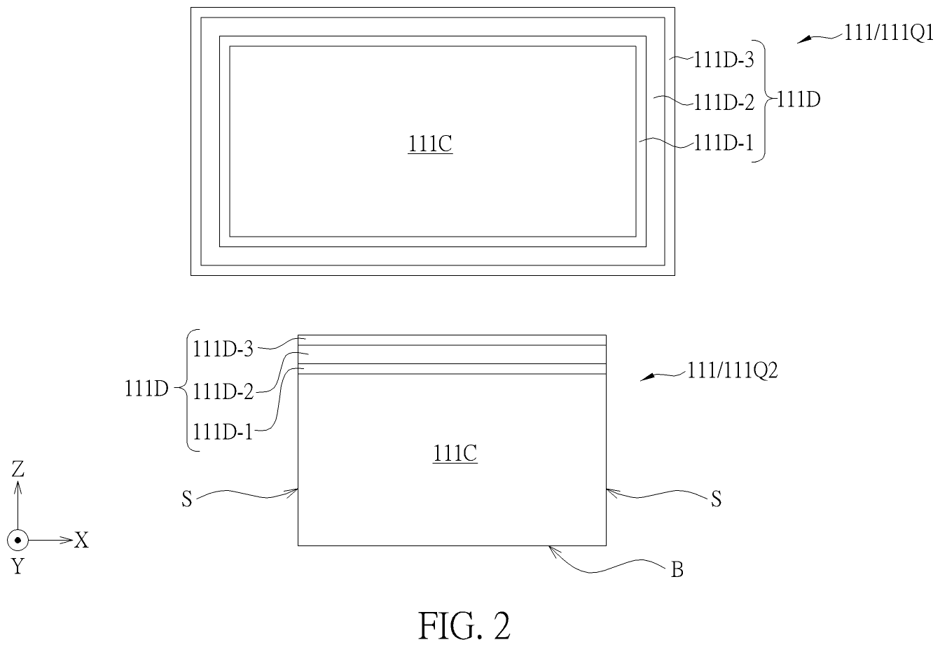

In some embodiments, the substrate 111 of the die 110 may be a semiconductor substrate, such as a silicon substrate or other semiconductor substrates. In other embodiments, the substrate 111 of the die 110 may be a composite substrate (or referred to as a QST substrate) composed of a core layer and a composite material layer. FIG. 2 shows schematic cross-sectional views of the substrate 111 of the die 110 in some embodiments of the present disclosure. In one embodiment, the substrate 111 may be a QST substrate 111Q1, which includes a core layer 111C and a composite material layer 111D wrapping around the core layer 111C. The composite material layer 111D may include multiple insulating layers and multiple semiconductor bonding layers arranged in sequence, such as a first insulating layer 111D-1, a semiconductor bonding layer 111D-2 and a second insulation layer 111D-3 wrapping around the core layer 111C from the inside to the outside in sequence, but not limited thereto. In some embodiments, the composition of the core layer 111C may be aluminum nitride (AlN), silicon carbide (Sic), aluminum oxide (Al₂O₃) (or referred to as a sapphire substrate) or a ceramic substrate composed of the combinations thereof. The first insulating layer 111D-1 and the second insulating layer 111D-3 may be insulating layers with the same or different compositions, such as oxides, nitrides, oxynitrides, or other suitable insulating materials. The composition of the semiconductor bonding layer 111D-2 may be silicon, but not limited thereto. Compared with a single crystal silicon substrate, the QST substrate used as the substrate 111 of the die 110 has higher mechanical strength and prevents from cracking or bending. Moreover, the QST substrate also provides better heat dissipation effect than the single crystal silicon substrate. For example, the thermal conductivity k value of the silicon substrate is about 1.1 W/m·absolute temperature (W/m·k), and the thermal conductivity k value of the QST substrate is about 220 W/m·k. The higher the thermal conductivity k value, the thermal conductivity effect is better. According to some embodiments of the present disclosure, the use of the QST substrate in the die provides excellent heat dissipation capability. For example, the heat dissipation capability of the QST substrate is much better than that of the silicon substrate, thereby greatly improving the heat dissipation effect of the package structure of the die.

Still referring to FIG. 1, according to some embodiments of the present disclosure, a backside metal layer (BM) 114 is formed on the second surface 111B of the substrate 111 of the die 110. The backside metal layer 114 may be a single-layered structure or a multi-layered structure. The composition of the single-layered structure is, for example, Au, Ag, Cu or a pre-solder material. The composition of the multi-layered structure may be selected from a group consisting of Ti/Ni/Ag, Ti/NiV/Ag, Ti/Ni/Au, Ti/Cu, Ti/Au, Cu/Ni/Au, Ni/Pd/Au, Ni/Au, Au/As, Al/Ni/Ag and combinations thereof. In one embodiment, the substrate 111 may be a silicon substrate, and the backside metal layer 114 may be formed on the back surface of the silicon substrate. Referring to FIG. 1 and FIG. 2, in one embodiment, the substrate 111 is the QST substrate 111Q1, and the backside metal layer 114 may be formed on the back surface of the QST substrate 111Q1 such as formed on the bottom surface of the second insulating layer 111D-3. In another embodiment, the substrate 111 is the QST substrate 111Q2. The QST substrate 111Q1 may be thinned on the backside thereof and diced by a cutting process, so that portions of the composite material layer 111D located on the bottom surface B and the side surfaces S of the core layer 111C are removed, and a portion of the composite material layer 111D located on the top surface of the core layer 111C is remained, thereby forming the QST substrate 111Q2. In this embodiment, the backside metal layer 114 formed on the back surface of the QST substrate 111Q2 is in contact with the bottom surface B of the core layer 111C. In some embodiments, the backside metal layer 114 may cover at least 60% of the second surface 111B of the substrate 111, for example about 60% to about 100% of the area of the second surface 111B. Moreover, the backside metal layer 114 is selected from metal materials whose surface is easily wetted by liquid or molten solder. For example, at least 80% of the surface of the backside metal layer 114 may be wetted by liquid or molten solder. Since the backside metal layer 114 forms a solder joint with a solder, forming the backside metal layer 114 on the second surface 111B of the substrate 111 of the die 110 facilitates subsequent use of a solder to solder the die 110 onto the lead frame 101.

In addition, the package structure 100 includes multiple bonding wires electrically connecting multiple bonding pads of the die 110 to multiple conductive pads of the lead frame 101 respectively. For example, a first bonding wire 121 electrically connects the first bonding pad 113-1 of the die 110 to a first conductive pad 105-1 of the lead frame 101, and a second bonding wire 122 electrically connects the second bonding pad 113-2 of the die 110 to a second conductive pad 105-2 of the lead frame 101. The package structure 100 further includes a molding material 130 to encapsulate the die 110 and the multiple bonding wires, such as the first bonding wire 121, the second bonding wire 122 and other bonding wires. The molding material 130 also covers the top surface of the lead frame 101. In one embodiment, the molding material 130 may be a polymer resin, for example, epoxy resin.

As shown in FIG. 1, the package structure 100 further includes a first solder 115 such as soldering tin disposed between the backside metal layer 114 and the cavity 103 of the lead frame 101. The die 110 is soldered onto the lead frame 101 through the solder joint between the first solder 115 and the backside metal layer 114. In addition, the package structure 100 also includes a printed circuit board 140 disposed below the lead frame 101, and a second solder 117 such as soldering tin disposed between the lead frame 101 and the printed circuit board 140. The lead frame 101 is soldered onto the printed circuit board 140 through the second solder 117. In this embodiment, the lead frame 101 further includes a through hole 104 disposed below the bottom surface of the cavity 103. The second solder 117 fills up the through hole 104 and is in contact with the backside metal layer 114 and the first solder 115. In one embodiment, the second solder 117 and the first solder 115 may have the same composition, so that there is no obvious boundary between the second solder 117 and the first solder 115. In another embodiment, the second solder 117 and the first solder 115 may have different compositions, so that there is a boundary between the second solder 117 and the first solder 115. Since the backside metal layer 114 is soldered to the second solder 117, the substrate 111 of the die 110 is directly soldered onto the printed circuit board 140 through the second solder 117. The second solder 117 may be disposed on a conductive pad (not shown) of the printed circuit board 140. Furthermore, the heat generated during the operation of the die 110 is directly dissipated to the printed circuit board 140 through the substrate 111, the through holes 104 of the lead frame 101, and the second solder 117, thereby improving the heat dissipation effect of the package structure 100.

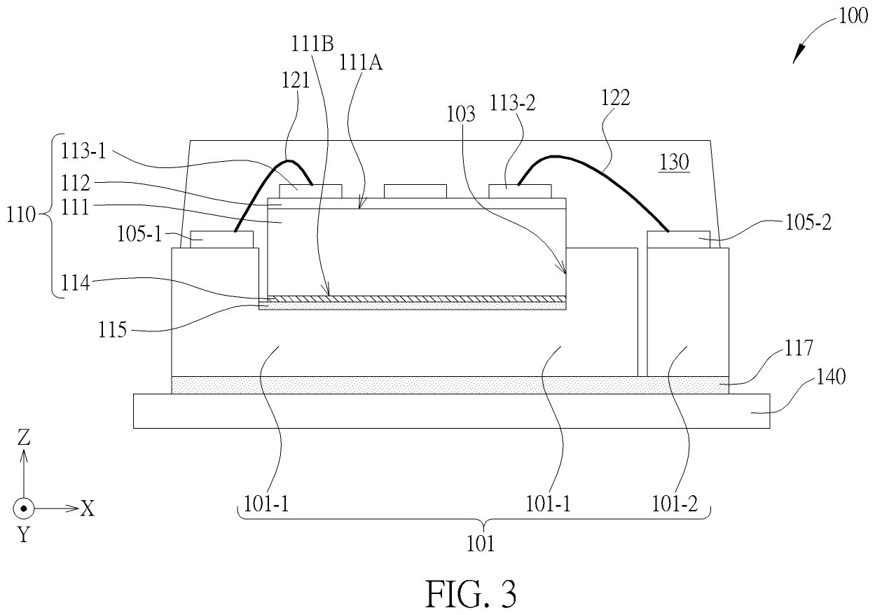

FIG. 3 is a schematic cross-sectional view of a package structure 100 according to another embodiment of the present disclosure. In the package structure 100 of FIG. 3, there is no through hole disposed below the bottom surface of the cavity 103 of the lead frame 101, and the first solder 115 is in contact with the entire bottom surface of the backside metal layer 114 and the entire bottom surface of the cavity 103. The second solder 117 is located between the lead frame 101 and the printed circuit board 140, and the second solder 117 is not in contact with the backside metal layer 114 and the first solder 115. The details of other features of the package structure 100 in FIG. 3 may refer to the aforementioned description of the package structure 100 in FIG. 1, and are not repeated herein.

In the conventional package structure of a die, the die is attached on the lead frame by using silver glue. The thermal conductivity k value of the silver glue is about 2 W/m·k. In the package structures 100 of some embodiments of the present disclosure, the thermal conductivity k value of the first solder 115 and the second solder 117 is about 64 W/m·k. The heat dissipation effect of the first solder 115 and the second solder 117 is about 30 times more than that of the silver glue. In the package structures of some embodiments of the present disclosure, the first solder 115 is used to replace the silver glue used in the conventional package structure of the die, thereby improving the heat dissipation effect of the package structures by more than 30 times that of the conventional package structure. Moreover, in the package structures 100 of some embodiments of the present disclosure, the cavity 103 is formed in the lead frame 101, and the die 110 is disposed in the cavity 103, thereby reducing the height of the package structures. For example, compared with a package structure using a lead frame without a cavity, the package structures of some embodiments of the present disclosure may reduce the height of the package structures by about 15% to about 25%, which is conducive to the requirement of miniaturization in the package size of the die.

Furthermore, in some embodiments of the present disclosure, the substrate 111 of the die 110 may use a QST substrate instead of a silicon substrate. The thermal conductivity k value of the silicon substrate is about 1.1 W/m·k, and the thermal conductivity k value of the QST substrate is about 220 W/m·k. Therefore, using the QST substrate improves the heat dissipation effect of the package structures. Moreover, in some embodiments of the present disclosure, the backside metal layer 114 is formed on the back surface of the QST substrate, thereby soldering the die 110 onto the lead frame 101 through the first solder 115 without using silver glue. The heat dissipation effect of the solder material of the first solder 115 is dozens of times that of the silver glue. Therefore, the package structures of some embodiments of the present disclosure greatly improve the heat dissipation effect by using the QST substrate, the backside metal layer 114 and the first solder 115.

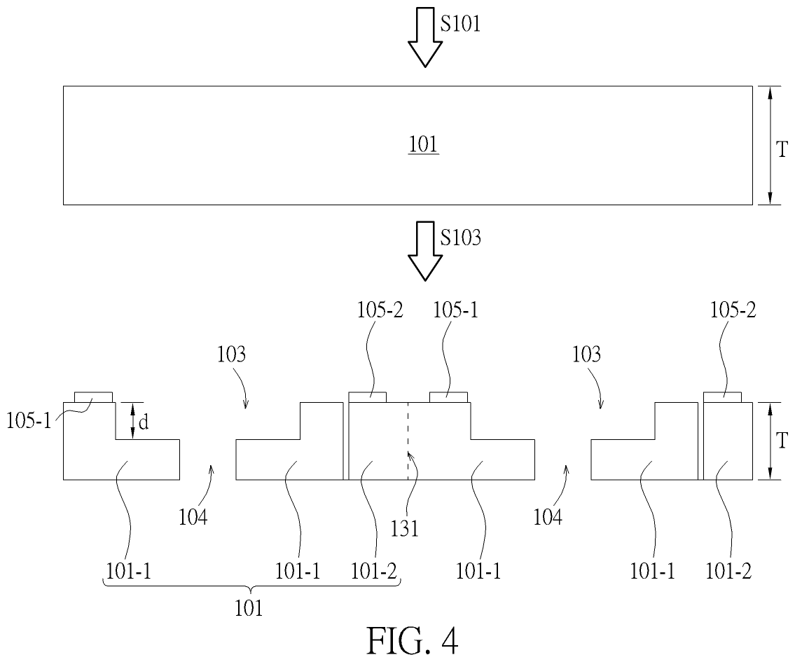

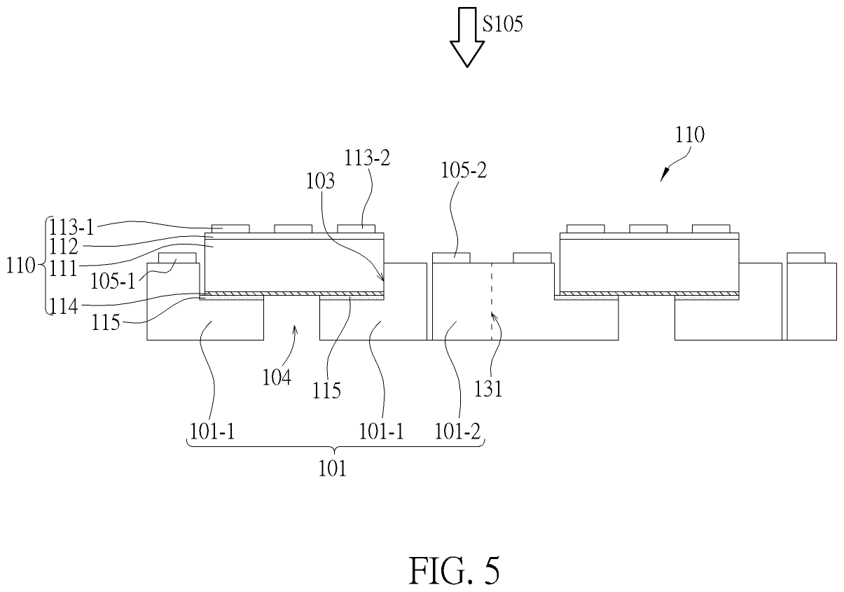

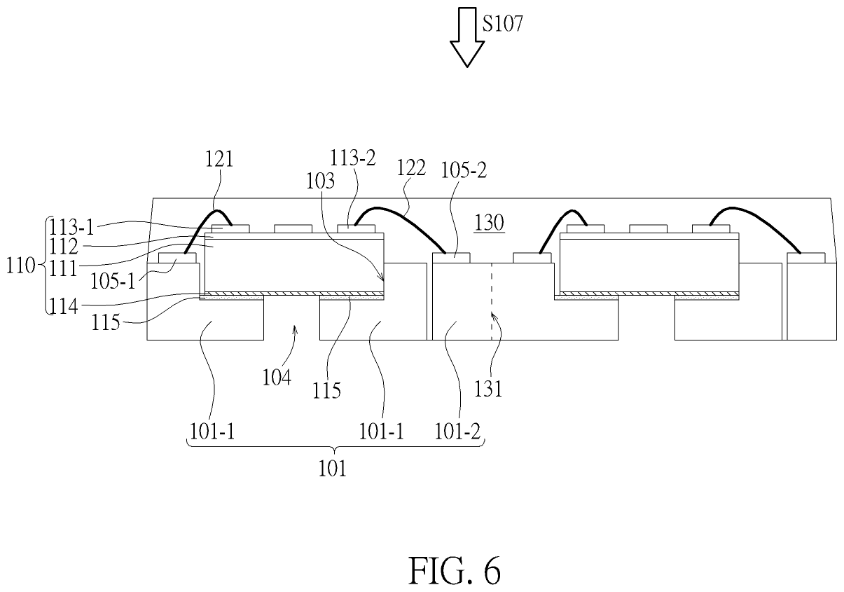

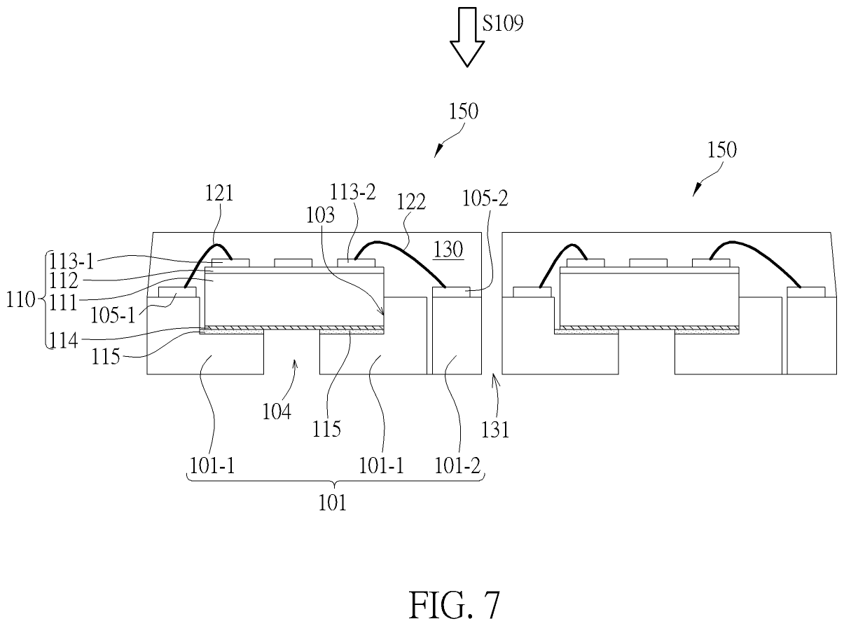

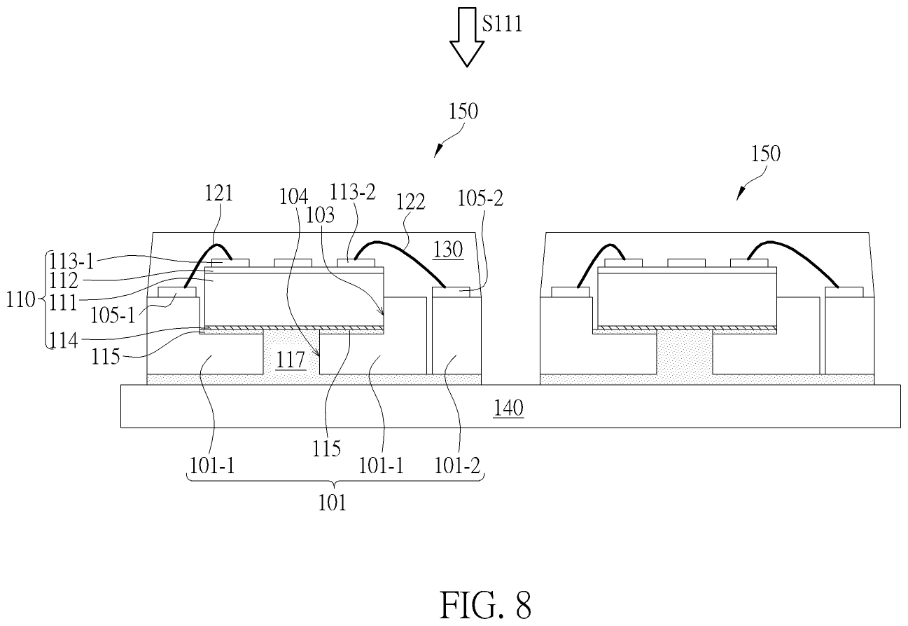

FIG. 4, FIG. 5, FIG. 6, FIG. 7 and FIG. 8 are schematic cross-sectional views of some stages of a method of fabricating a package structure according to an embodiment of the present disclosure. Referring to FIG. 4, in step S101, a lead frame 101 such as a copper lead frame is provided. In some embodiments, the thickness T of the lead frame 101 is, for example, about 400 μm. Still referring to FIG. 4, in step S103, a cavity 103 is formed in the lead frame 101 by an etching process. In some embodiments, the depth d of the cavity 103 is, for example, about 100 μm, but not limited thereto. The lead frame 101 with the cavity 103 formed therein still provides sufficient support for a die during the packaging process. For example, as the thickness T of the lead frame 101 is larger, the depth d of the cavity 103 may be increased accordingly. Then, the lead frame 101 may be drilled by a mechanical drilling process to form a through hole 104 under the bottom surface of the cavity 103, and the through hole 104 is connected to the cavity 103. In addition, multiple conductive pads such as a first conductive pad 105-1 and a second conductive pad 105-2 may be formed on the lead frame 101, and located on a first portion 101-1 and a second portion 101-2 of the lead frame 101, respectively. The first portion 101-1 and the second portion 101-2 corresponding to the same die are laterally separated from each other. In addition, the predetermined area of forming a scribe line 131 is located between the first portion 101-1 corresponding to one die and the second portion 101-2 corresponding to another adjacent die.

Referring to FIG. 5, in step S105, multiple dies 110 are provided. These dies 110 are simultaneously disposed in the multiple cavities 103 of the lead frame 101 respectively. In addition, these dies 110 are soldered onto the lead frame 101 by using a first solder 115. In the production of the die 110, a semiconductor layer 112 is formed on a first surface 111A of a substrate 111 of the die 110 by an epitaxial growth process. In one embodiment, the semiconductor layer 112 may be a gallium nitride (GaN) layer, but not limited thereto. Referring to FIG. 2 again, in one embodiment, the substrate 111 may be the QST substrate 111Q2, where the composition of the core layer 111C is, for example, aluminum nitride (AlN), and the composite material layer 111D is located on the top surface of the core layer 111C. Then, multiple bonding pads, such as a first bonding pad 113-1 and a second bonding pad 113-2, are formed on the semiconductor layer 112 by deposition, photolithography and etching processes. Moreover, an insulating polymer layer (not shown) may be optionally formed between the semiconductor layer 112 and the multiple bonding pads. The composition of the insulating polymer layer is, for example, polyimide (PI) or polymerized benzocyclobutene (BCB), but not limited thereto. In addition, a redistribution layer (RDL) may be formed between the insulating polymer layer and the semiconductor layer 112. The RDL includes multiple dielectric layers and multiple conductive layers. The dielectric layer is, for example, a silicon oxide layer, and the conductive layer is, for example, copper or aluminum wire layer.

In addition, a backside metal layer 114 is formed on a second surface 111B of the substrate 111 of the die 110 by evaporation, sputtering, electroless plating or plating process. In one embodiment, the backside metal layer 114 is, for example, a multi-layered structure of Ti/Ni/Ag. The details of the other features of the die 110 may refer to the aforementioned description of FIG. 1, and are not repeated herein. According to some embodiments of the present disclosure, since the backside metal layer 114 is formed on the back surface of the die 110, the die 110 is soldered onto the lead frame 101 through the first solder 115. After the first solder 115 is applied onto the bottom surface of the cavity 103, and the die 110 is disposed in the cavity 103, a reflow process is performed to solder the die 110 onto the lead frame 101, so that the die 110 is attached on the lead frame 101.

Referring to FIG. 6, in step S107, after the die 110 is soldered and attached onto the lead frame 101 through the first solder 115, a wiring process is performed to form multiple bonding wires, and the multiple bonding pads of the die 110 are electrically connected to the lead frame 101 through the multiple bonding wires respectively. For example, a first bonding wire 121 is formed to electrically connect the first bonding pad 113-1 of the die 110 to the first conductive pad 105-1 of the lead frame 101, and a second bonding wire 122 is formed to electrically connect the second bonding pad 113-2 of the die 110 to the second conductive pad 105-2 of the lead frame 101. In some embodiments, the bonding wire is, for example, an Au wire, a Cu wire, a PdCu wire, an Ag wire or other metal wires. Since the die 110 is soldered and attached onto the lead frame 101 through the first solder 115, the position of the die 110 is not skewed or shifted during the wiring process, thereby improving the yield and the quality of the package structures. Next, a molding material 130, such as a molding compound or other dielectric material, is coated to encapsulate the multiple dies 110 and the multiple bonding wires, and the molding material 130 also covers the lead frame 101.

Referring to FIG. 7, in step S109, after using the molding material 130 to encapsulate the multiple dies 110 and the multiple bonding wires, the molding material 130, the multiple dies 110 and the lead frame 101 are diced along the scribe line 131 by using a blade saw and a die break dicing process to form multiple single-die packages 150.

Afterwards, referring to FIG. 8, in step S111, a printed circuit board 140 is provided, and a second solder 117 is applied onto the printed circuit board 140. Then, the multiple single-die packages 150 are disposed on the printed circuit board 140, where the second solder 117 is located between the lead frame 101 and the printed circuit board 140. A reflow process is performed to solder the lead frame 101 onto the printed circuit board 140 through the second solder 117, so that the multiple single-die packages 150 are soldered onto the printed circuit board 140 to complete the package structure 100 of FIG. 1. In this embodiment, after the reflow process, the second solder 117 fills up the through hole 104 of the lead frame 101, and the second solder 117 is in contact with the first solder 115 and the backside metal layer 114 of the die 110.

Moreover, the package structure 100 of FIG. 2 may also be completed by the fabrication method as shown in FIG. 4 to FIG. 8. The difference between the methods of fabricating the package structures 100 of FIG. 2 and FIG. 1 is that for the package structure 100 of FIG. 2, in step S103 of FIG. 4, no through hole is formed under the cavity 103 of the lead frame 101.

The package structures of the embodiments of the present disclosure are suitable for various types of packages, such as transistor outline (TO) package, small outline integrated circuit (SOIC) package, quad flat package (QFP), dual flat no-lead (DEN) package, quad flat no-lead (QFN) package, ball grid array (BGA) package or other types of packages.

According to some embodiments of the present disclosure, the cavity is formed in the lead frame, the backside metal layer is formed on the back surface of the die, the die is disposed in the cavity of the lead frame, and the backside metal layer of the die is soldered onto the lead frame through the solder. The height of the package structures is reduced by the cavity of the lead frame, and the heat dissipation effect of the package structures is improved by the solder joint between the solder and the backside metal layer. Moreover, when the QST substrate is used as the substrate of the die, the heat dissipation effect of the package structures is greatly improved. Therefore, the package structures of the present disclosure are more suitable for the semiconductor devices operated at high voltage and high temperature, such as high-frequency and high-power semiconductor devices made of group III-V compound semiconductors.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A package structure, comprising:
a lead frame, comprising a cavity;
a die, disposed in the cavity, wherein the die comprises:
a substrate, having a first surface and a second surface;
a bonding pad, disposed on the first surface; and
a backside metal layer, disposed on the second surface;
a bonding wire, electrically connecting the bonding pad to the lead frame;
a first solder, disposed between the backside metal layer and the cavity, wherein the die is soldered onto the lead frame through the first solder; and
a molding material, encapsulating the die and the bonding wire, and covering the lead frame.

2. The package structure of claim 1, further comprising:
a printed circuit board, disposed below the lead frame; and
a second solder, disposed between the lead frame and the printed circuit board, wherein the lead frame is soldered onto the printed circuit board through the second solder.

3. The package structure of claim 2, wherein the lead frame further comprises a through hole disposed under a bottom surface of the cavity.

4. The package structure of claim 3, wherein the second solder fills up the through hole, and the second solder is in contact with the backside metal layer and the first solder.

5. The package structure of claim 1, wherein the substrate comprises a core layer and a composite material layer wrapping around the core layer, or a semiconductor substrate.

6. The package structure of claim 5, wherein the composition of the semiconductor substrate comprises silicon, the composition of the core layer comprises aluminum nitride, silicon carbide, aluminum oxide or a combination thereof, and the composite material layer comprises an insulating layer and a semiconductor bonding layer.

7. The package structure of claim 5, wherein the backside metal layer is in contact with a bottom surface of the core layer.

8. The package structure of claim 1, wherein the backside metal layer comprises a single-layered structure or a multi-layered structure, the composition of the single-layered structure comprises Au, Ag, Cu or a pre-solder material, and the composition of the multi-layered structure is selected from a group consisting of Ti/Ni/Ag, Ti/NiV/Ag, Ti/Ni/Au, Ti/Cu, Ti/Au, Cu/Ni/Au, Ni/Pd/Au, Ni/Au, Au/As, Al/Ni/Ag and a combination thereof.

9. The package structure of claim 1, wherein the die further comprises a semiconductor layer disposed on the first surface of the substrate, the bonding pad is disposed on the semiconductor layer, and the composition of the semiconductor layer comprises silicon or a group III-V compound semiconductor.

10. The package structure of claim 1, wherein a depth of the cavity is one-quarter to one-half of a thickness of the lead frame.

11. A method of fabricating a package structure, comprising:
providing a lead frame and forming a cavity in the lead frame;
providing a die, comprising:
providing a substrate having a first surface and a second surface;
forming a bonding pad on the first surface; and
forming a backside metal layer on the second surface;
disposing the die in the cavity;
using a first solder to solder the backside metal layer of the die onto the lead frame;
forming a bonding wire to electrically connect the bonding pad to the lead frame; and
using a molding material to encapsulate the die and the bonding wire, and cover the lead frame.

12. The method of claim 11, further comprising:
providing a printed circuit board to be disposed below the lead frame; and
using a second solder to solder the lead frame onto the printed circuit board.

13. The method of claim 12, further comprising forming a through hole under a bottom surface of the cavity.

14. The method of claim 13, wherein the second solder fills up the through hole and is in contact with the backside metal layer and the first solder.

15. The method of claim 13, wherein forming the cavity comprises an etching process, and forming the through hole comprises a mechanical drilling process.

16. The method of claim 11, wherein providing the substrate comprises providing a semiconductor substrate, or providing a core layer and forming a composite material layer to wrap around the core layer.

17. The method of claim 16, wherein the composition of the semiconductor substrate comprises silicon, the composition of the core layer comprises aluminum nitride, silicon carbide, aluminum oxide or a combination thereof, and the composite material layer comprises an insulating layer and a semiconductor bonding layer.

18. The method of claim 11, wherein forming the backside metal layer comprises evaporation, sputtering or plating process, and the backside metal layer comprises a single-layered structure or a multi-layered structure, the composition of the single-layered structure comprises Au, Ag, Cu or a pre-solder material, and the composition of the multi-layered structure is selected from a group consisting of Ti/Ni/Ag, Ti/NiV/Ag, Ti/Ni/Au, Ti/Cu, Ti/Au, Cu/Ni/Au, Ni/Pd/Au, Ni/Au, Au/As, Al/Ni/Ag and a combination thereof.

19. The method of claim 11, wherein providing the die further comprises forming a semiconductor layer on the first surface, the bonding pad is formed on the semiconductor layer, and the composition of the semiconductor layer comprises silicon or a group III-V compound semiconductor.

20. The method of claim 12, wherein providing the lead frame comprises forming a plurality of cavities therein, and the method further comprises:
providing a plurality of dies, and simultaneously disposing the plurality of die in the plurality of cavities, respectively;
using the first solder to solder the plurality of dies to the lead frame;
using the molding material to encapsulate the plurality of dies;
dicing the molding material, the plurality of dies and the lead frame to form a plurality of single-die packages; and
using the second solder to solder the plurality of single-die packages onto the printed circuit board.
